(19) United States
(12) Patent Application Publication
(10) Pub. No.: US 2011/0278540 A1
(43) Pub. Date: Nov. 17, 2011

(54) FIELD-EFFECT TRANSISTOR

(75) Inventors: Kenichiro Tanaka, Osaka (JP); Tetsuzo Ueda, Osaka (JP); Hisayoshi Matsuo, Toyama (JP); Masahiro Hikita, Toyama (JP)

(73) Assignee: Panasonic Corporation, Osaka (JP)

(21) Appl. No.: 13/111,357

(22) Filed: May 19, 2011

Related U.S. Application Data
(63) Continuation of application No. PCT/JP2009/006176, filed on Nov. 18, 2009.

(30) Foreign Application Priority Data
Nov. 21, 2008 (JP) 2008-298735

(51) Int. Cl. H01L 29/12

(52) U.S. Cl. 257/20; 257/194; 257/E29.069; 257/76

(57) ABSTRACT

Provided is a field-effect transistor which is capable of suppressing current collapse. An HEMT as the field-effect transistor includes: a first semiconductor layer made of a first nitride semiconductor; and a second semiconductor layer formed on the first semiconductor layer and made of a second nitride semiconductor having a greater band gap than a band gap of the first nitride semiconductor, wherein the first semiconductor layer includes a region in which a threading dislocation density increases in a stacking direction.

### CROSS REFERENCE TO RELATED APPLICATION

This is a continuation application of PCT application No. PCT/JP2009/006176 filed on Nov., 18, 2009, designating the United States of America.

### BACKGROUND OF THE INVENTION

(1) Field of the Invention

The present invention relates to a field-effect transistor made of a nitride semiconductor which can be applied to a power transistor in a power supply circuit of a consumer appliance such as an air conditioner.

(2) Description of the Related Art

A nitride semiconductor has a greater band gap, a greater breakdown field, and a greater saturated drift velocity of electrons than Si, GaAs, and so on. Moreover, in an AlGaN/GaN heterostructure formed on a substrate having a (0001) plane as a main plane, a two-dimensional electron gas is generated in a hetero interface by spontaneous polarization and piezo polarization, and the sheet carrier density of 1×10¹³ cm⁻² or more can be obtained without any doping. In recent years, a high electron mobility transistor (HEMT) in which the highly-concentrated two-dimensional electron gas is used as a carrier has received attention, and HEMTs having various structures have been proposed.

FIG. 13 is a cross-sectional view showing a conventional field-effect transistor having an AlGaN/GaN heterostructure (e.g., refer to Patent Reference 1: Japanese Unexamined Patent Application Publication No. 2007-251144).

In a conventional field-effect transistor 700 made of a nitride semiconductor shown in the view, a low-temperature AlN buffer layer 702, an undoped GaN layer 703, and an undoped AlGaN layer 704 are formed above a Si substrate 701 in this order. Furthermore, a source electrode 705 and a drain electrode 707 that are composed of a Ti layer and an Al layer are formed on the undoped AlGaN layer 704. Moreover, a gate electrode 706 that is composed of a Ni layer, a Pt layer, and an Au layer is formed between the source electrode 705 and the drain electrode 707. Furthermore, an SiN layer (not shown in the view) is formed as a passivation film.

In the field-effect transistor 700 having such a structure, a two-dimensional electron gas generated in an interface between the undoped AlGaN layer 704 and the undoped GaN layer 703 is used as a carrier. Applying a voltage between a source and a drain moves electrons in a channel from the source electrode 705 to the drain electrode 707. Here, a thickness of a depletion layer directly below the gate electrode 706 is varied by controlling the voltage applied to the gate electrode 706, and thus it is possible to control the electrons moving from the source electrode 705 to the drain electrode 707, that is, a drain current.

### SUMMARY OF THE INVENTION

However, a phenomenon called current collapse is observed in such an HEMT including GaN, and it is known that the current collapse causes problems at the time of operating a device. This phenomenon is that once a strong electric filed is applied between a source and a drain, a source and a gate, a drain and a substrate, and so on, a channel current between the source and drain is subsequently reduced.

In view of the above problem, the present invention has an object to provide a field-effect transistor capable of suppressing current collapse.

In order to solve the above problem, the field-effect transistor according to the present invention includes: a first semiconductor layer made of a first nitride semiconductor; and a second semiconductor layer formed on the first semiconductor and made of a second nitride semiconductor having a greater band gap than a band gap of the first nitride semiconductor, wherein the first semiconductor layer has a region in which a threading dislocation density increases in a stacking direction. Here, it is preferred that the threading dislocation density in a contact plane between the first and second semiconductor layers is equal to or higher than 2×10⁹ cm⁻².

With this, in the field-effect transistor in which a portion where the first and second semiconductor layers contact with each other is a channel, it is possible to increase the threading dislocation density of the first semiconductor layer of the channel so as to prevent the current collapse from being deteriorated. As a result, it is possible to realize the field-effect transistor which is capable of suppressing the current collapse.

Furthermore, the first semiconductor layer may include a third semiconductor layer, a crystallinity control layer formed on the third semiconductor layer, and a fourth semiconductor layer formed on the crystallinity control layer, the crystallinity control layer may have a threading dislocation density increasing in a stacking direction, and the fourth semiconductor layer may have a threading dislocation density greater than a threading dislocation density of the third semiconductor layer.

With this, a portion of the first semiconductor layer is a layer having a high threading dislocation density and the rest of the first semiconductor layer is a layer having a low threading dislocation density, and thus it is possible to increase a film thickness of the first semiconductor layer. As a result, it is possible to combine the suppression of the current collapse with an increase of a breakdown voltage.

Moreover, the first semiconductor layer may include a region in which a threading dislocation density decreases in a stacking direction.

With this, it is possible to reduce the threading dislocation density in a contact plane of the first semiconductor layer with the second semiconductor layer to or to less than 1.6×10¹⁰ cm⁻², and limit sheet resistance to a practically usable range. In addition, the film thickness of the first semiconductor layer can be increased, and thus it is possible to realize a high-breakdown voltage field-effect transistor.

Furthermore, first semiconductor layer may have the film thickness equal to or greater than 2 μm.

With this, it is possible to realize the high-breakdown voltage.

The present invention realizes the high-breakdown voltage field-effect transistor capable of suppressing the current collapse.

### FURTHER INFORMATION ABOUT TECHNICAL BACKGROUND TO THIS APPLICATION

The disclosure of Japanese Patent Application No. 2008-298735 filed on Nov. 21, 2008 including specification, drawings and claims is incorporated herein by reference in its entirety.

The disclosure of PCT application No. PCT/JP2009/006176 filed on Nov. 18, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view schematically showing a structure of an HEMT as a nitride field-effect transistor according to an embodiment of the present invention;

FIG. 2 is a diagram showing a relationship between a full width at half maximum of a (1012) line of an X-ray rocking curve and a degree of current collapse Raf/Rbf;

FIG. 3 is a diagram showing a relationship between the full width at half maximum of the (1012) line of the X-ray rocking curve and a threading dislocation density;

FIG. 4 is a graph showing a relationship between the full width at half maximum of the (1012) line of the X-ray rocking curve and a sheet resistance of a channel;

FIG. 5 is a graph showing a relationship between the full width at half maximum of the (1012) line of the X-ray rocking curve and a film thickness of a first nitride semiconductor layer;

FIG. 6 is a cross-sectional view schematically showing a structure of an HEMT according to Example 1;

FIG. 7 is a graph schematically showing a variation in the full width at half maximum of the (1012) line of the X-ray rocking curve in a stacking direction in an HEMT according to each of examples;

FIG. 8 is a cross-sectional view schematically showing a structure of an HEMT according to Example 2;

FIG. 9 is a cross-sectional view schematically showing a modification of the structure of the HEMT according to Example 2;

FIG. 10 is a cross-sectional view schematically showing a modification of the structure of the HEMT according to Example 2;

FIG. 11 is a cross-sectional view schematically showing a structure of an HEMT according to Example 3;

FIG. 12 is a cross-sectional view schematically showing a structure of an HEMT according to Example 4; and

FIG. 13 is a cross-sectional view schematically showing a structure of a conventional field-effect transistor.

### DESCRIPTION OF THE PREFERRED EMBODIMENTS

The following describes a filed-effect transistor according to an embodiment of the present invention with reference to the drawings.

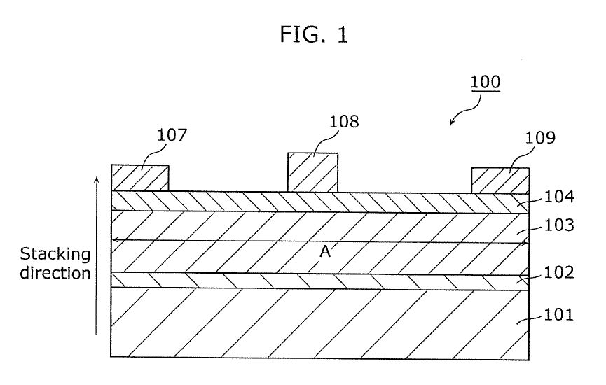

FIG. 1 is a cross-sectional view schematically showing a structure of an HEMT 100 as a field-effect transistor according to this embodiment of the present invention.

As shown in FIG. 1, the HEMT 100 includes a first nitride semiconductor layer 103 and a second nitride semiconductor layer 104 that are sequentially stacked via a buffer layer 102 above a substrate 101. The HEMT 100 includes a source electrode 107, a gate electrode 108, and a drain electrode 109 that are formed side by side on the second nitride semiconductor layer 104.

The first nitride semiconductor layer 103 is an example of a first semiconductor layer according to the present invention, and is a layer which is formed on the buffer layer 102 and made of a first nitride semiconductor. The second nitride semiconductor layer 104 is an example of a second semiconductor layer according to the present invention, and is a layer which is formed on the first nitride semiconductor layer 103 and made of a second nitride semiconductor having a greater band gap than a band gap of the first nitride semiconductor.

The following describes the first nitride semiconductor layer 103 included in the HEMT 100.

The inventors predicted that there would be a correlation between crystallinity of a channel of the first nitride semiconductor layer 103 and current collapse in the HEMT 100. The inventors produced HEMTs 100 having the structure shown in FIG. 1 by varying the crystallinity of the first nitride semiconductor layer 103, and examined the first nitride semiconductor layer 103 for a correspondence relationship between the current collapse and a full width at half maximum of a (1012) line of an X-ray rocking curve. It is to be noted that a sample in which the first nitride semiconductor layer 103 made of GaN having the thickness of 2 μm was used as a measurement sample.

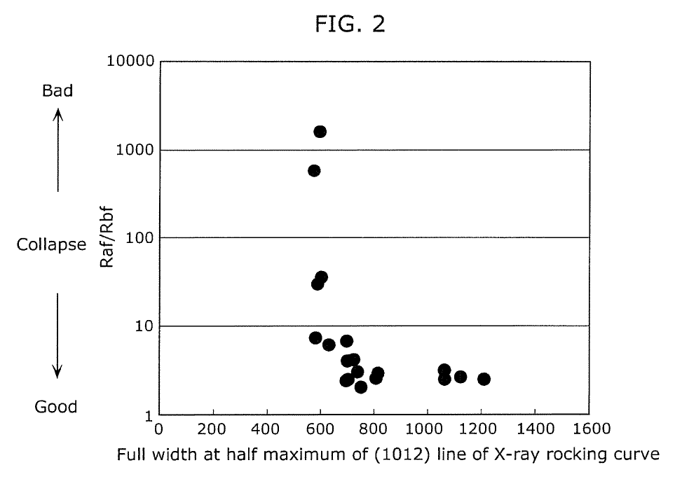

FIG. 2 is a graph showing a relationship between a full width at half maximum of a (1012) line of an X-ray rocking curve and a degree of current collapse Raf/Rb.

Here, the full width at half maximum of the (1012) line of the X-ray rocking curve indicates a full width at half maximum of a rocking curve which is measured by a ω scan mode and obtained by X-ray diffraction with respect to a (1012) plane. A value of the full width at half maximum of the (1012) line of the X-ray rocking curve shown in FIG. 2 indicates a rocking curve by X-ray diffraction using Cu—Kα rays (wavelength λ=1.54 Å). It is to be noted that x-rays used in obtaining a rocking curve is not necessarily limited to the Cu—Kα rays, and other x-rays such as Mo—Kα rays may be used.

A method of measuring the degree of current collapse shown in FIG. 2 is as follows. For instance, in the HEMT 100 having the structure shown in FIG. 1, 0 V is applied to the source electrode 107, the gate electrode 108, and the substrate 101, 2 V is applied to the drain electrode 109, and resistance between the source and the drain is measured. Here, the measured resistance is denoted by Rbf. Next, the HEMT 100 is turned off by temporarily applying −5 V and 200 V to the gate electrode 108 and the drain electrode 109, respectively, and the off-state is held for 30 seconds. Subsequently, 2 V is applied to the drain electrode 109 again, and resistance between the source and the drain is measure. Here, the measured resistance is denoted by Raf. At this time, the current collapse occurs, and the resistance between the source and the drain increases. It is possible to use an increase rate Raf/Rbf as an index showing magnitude of the current collapse.

As shown in FIG. 2, the higher the degree of the current collapse Raf/Rbf is, the more the current collapse is deteriorated, and the lower the degree of the current collapse is, the better the current collapse is. Furthermore, the smaller the full width at half maximum of the (1012) line of the X-ray rocking curve becomes, the degree of current collapse increases (the current collapse is deteriorated). In particular, when the full width at half maximum of the (1012) line of the X-ray rocking curve is equal to or less than 800 arc seconds, the current collapse is significantly deteriorated. Thus, the first nitride semiconductor layer 103 is formed so that the full width at half maximum of the (1012) line of the X-ray rocking curve becomes equal to or less than 800 arc seconds in a contact plane with the second nitride semiconductor layer 104. It is preferred that the first nitride semiconductor layer 103 is formed so that the full width at half maximum of the (1012) line of the X-ray rocking curve becomes equal to or less than 800 arc second in a portion, which is in contact with the second nitride semiconductor layer 104, of the first nitride semiconductor layer 103 functioning as the channel (a portion of the first nitride semiconductor layer 103 within a range of 100 nm from the contact plane with the second nitride semiconductor layer 104).

Here, it is possible to correspond the full width at half maximum of the (1012) line of the X-ray rocking curve of the first nitride semiconductor layer 103 to the threading dislocation density in the first nitride semiconductor layer 103.

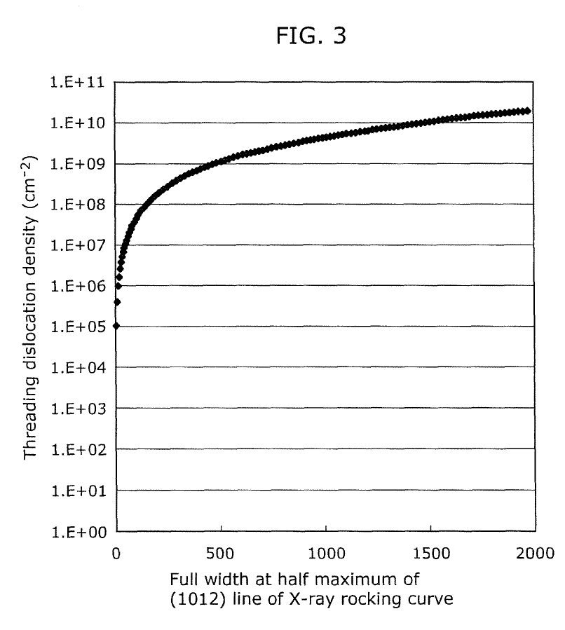

FIG. 3 is a graph showing a relationship between the full width at half maximum of the (1012) line of the X-ray rocking curve of the first nitride semiconductor layer 103 and the threading dislocation density in the first nitride semiconductor layer 103 (see Non Patent Reference 1: P. Gay, P. B. Hirsch, A. Kelly, Acta Metal, 1 (1953), 315.).

As shown in FIG. 3, 800 arc seconds or more in the full width at half maximum of the (1012) line of the X-ray rocking curve of the first nitride semiconductor layer 103 are equivalent to the threading dislocation density of 2×10⁹ cm⁻² or more in the first nitride semiconductor layer 103. Thus, the first nitride semiconductor layer 103 is formed so that the threading dislocation density becomes 2×10⁹ cm⁻² or more in the contact plane of the first nitride semiconductor layer 103 with the second nitride semiconductor layer 104, or more preferably the portion, which is in contact with the second nitride semiconductor layer 104, of the first nitride semiconductor layer 103 functioning as the channel.

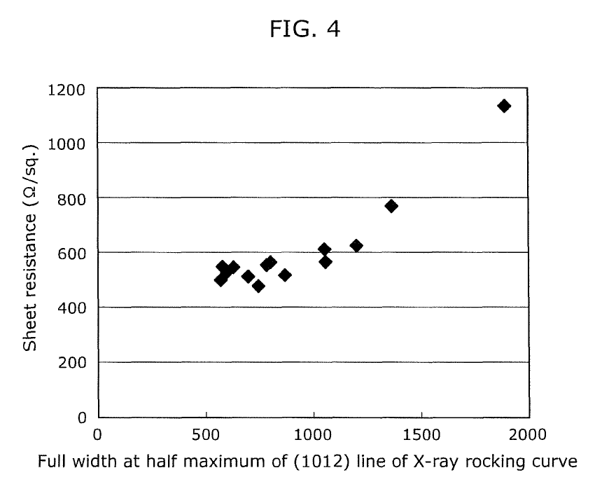

FIG. 4 is a graph showing a relationship between the full width at half maximum of the (1012) line of the X-ray rocking curve and sheet resistance of the channel.

As shown in FIG. 4, observed is a tendency that the sheet resistance of the first nitride semiconductor layer 103 functioning as the channel increases as the full width at half maximum of the (1012) line of the X-ray rocking curve of the first nitride semiconductor layer 103 becomes wider. Here, when the sheet resistance is equal to or less than 1200 Ω/sq., the first nitride semiconductor layer 103 can be practically used. Thus, the full width at half maximum of the (1012) line of the X-ray rocking curve needs to be equal to or less than 1900 arc seconds. Referring to FIG. 3, 1900 arc seconds or less in the full width at half maximum of the (1012) line of the X-ray rocking curve are equivalent to the threading dislocation density of 1.6×10¹⁰ cm⁻² or less. As a result, the first nitride semiconductor layer 103 is formed so that the threading dislocation density becomes 1.6×10¹⁰ cm⁻² or less in the contact plane of the first nitride semiconductor layer 103 with the second nitride semiconductor layer 104. It is preferred that the first nitride semiconductor layer 103 is formed so that the threading dislocation density becomes 1.6×10¹⁰ cm⁻² or less in the portion, which is in contact with the second semiconductor layer 104, of the first nitride semiconductor layer 103 functioning as the channel.

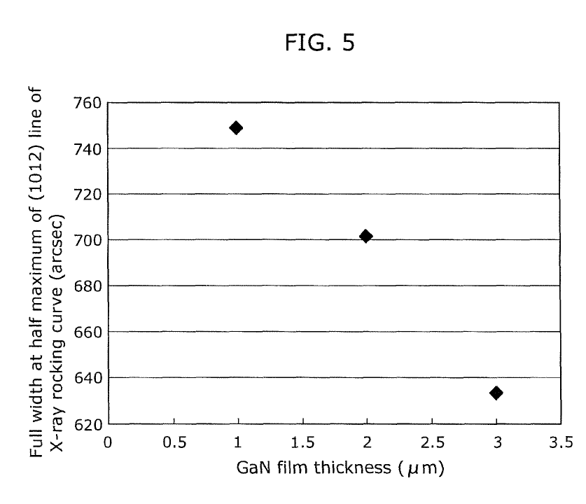

Here, when the first nitride semiconductor layer 103 having the thickness of 1 μm is used, a breakdown voltage of the HEMT 100 becomes equal to or less than 400 V, and thus the first nitride semiconductor layer 103 does not practically have a sufficient breakdown voltage. This is because when a strong voltage is applied between the source and the drain, a breakdown between the source and the drain occurs through the conductive substrate 101. Thus, in order to produce the HEMT 100 having a higher breakdown voltage, it is necessary to increase a breakdown voltage between the source and the substrate as well as the drain and the substrate, that is, to increase a film thickness of the first nitride semiconductor layer 103. It is preferred that a required film thickness of the first nitride semiconductor layer 103 is (i) 4 μm or more when, for example, the breakdown voltage of 800 V or more is required as the breakdown voltage of the HEMT 100, (ii) 3 μm or more when, for example, the breakdown voltage of 600 V or more is required as the breakdown voltage of the HEMT 100, and (iii) 2 μm or more when, for example, the breakdown voltage of 400 V or more is required as the breakdown voltage of the HEMT 100. However, as shown by the graph of FIG. 5 showing a relationship between the full width at half maximum of the (1012) line of the X-ray rocking curve and the film thickness of the first nitride semiconductor layer 103, generally, increasing the film thickness of the first nitride semiconductor layer 103 reduces the threading dislocation density due to extinction of dislocation, and the full width at half maximum of the (1012) line of the X-ray rocking curve becomes narrower. Consequently, the current collapse is deteriorated. In other words, generated is a trade-off that although the breakdown voltage or mobility becomes higher as the film thickness of the first nitride semiconductor layer 103 increases, the current collapse is inversely deteriorated.

The inventors found that a layer for widening the full width at half maximum of the (1012) line of the X-ray rocking curve is inserted as a portion of the first nitride semiconductor layer 103 so that the trade-off between the deterioration in the current collapse and the increase of the film thickness of the first nitride semiconductor layer 103 required for increasing the breakdown voltage is overcome, and thus the current collapse is ameliorated. Accordingly, provided in the first nitride semiconductor layer 103 is a region which is for widening the full width at half maximum of the (1012) line of the X-ray rocking curve and in which a threading dislocation density increases in a stacking direction. Here, although the region in which the threading dislocation density increases in the stacking direction may be provided, with respect to the stacking direction, in a tiny region in the first nitride semiconductor layer 103, it is preferred that the region is provided, with respect to a direction perpendicular to the stacking direction (in-plane direction), in a region having a width equal to or more than a predetermined width in the first nitride semiconductor layer 103. More specifically, it is preferred that the region is provided in a region having a width of the in-plane direction which is equal to or more than half of a distance between the source electrode 107 and the drain electrode 109. This is because although channel depletion in part of a channel over the tiny region in the first nitride semiconductor layer 103 is ameliorated when the threading dislocation density increases only in the tiny region in the stacking direction with respect to the in-plane direction, the channel depletion is not ameliorated in another part of the channel, and it cannot be the that the current collapse is not sufficiently ameliorated when viewed from an overall characteristic of the HEMT 100. In order to ensure the amelioration of the current collapse, it is preferred that a region in which a threading dislocation density increases, in a stacking direction, across a substantially entire region in an in-plane direction, that is, a substantially entire region in which a channel is formed in the in-plane direction is provided in a region in which the channel of the first semiconductor layer 103 is formed and functions as the HEMT 100, that is, a region sandwiched by the source electrode 107 and the drain electrode 109 (region A in FIG. 1). Furthermore, it is preferred that another region in which a threading dislocation density decreases in a stacking direction is further provided in the first nitride semiconductor layer 103. Moreover, it is preferred that the film thickness of the first nitride semiconductor layer 103 is equal to 2 μm or more for increasing the breakdown voltage.

As described above, the HEMT 100 according to this embodiment is formed so that the threading dislocation density of the contact plane of the first nitride semiconductor layer 103 with the second nitride semiconductor layer 104 becomes between 2×10⁹ cm⁻² and 1.6×10¹⁰ cm⁻² inclusive. Thus, it is possible to suppress the current collapse while limiting the sheet resistance within a practically usable range.

Furthermore, in the HEMT 100 according to this embodiment, not all but part of the first semiconductor layer 103 (at least the contact plane of the first nitride semiconductor layer 103 with the second semiconductor layer 104, or preferably the range of 100 nm from the contact plane of the first semiconductor layer 103 functioning as the channel with the second nitride semiconductor layer 104) is a region having a high threading dislocation density equal to or higher than 2×10⁹ cm⁻², and another region is a region having a low threading dislocation density. Thus, it is possible to combine the suppression of the current collapse with the increase of the breakdown voltage.

### Example 1

Example 1 shows an application of the HEMT 100 according to this embodiment.

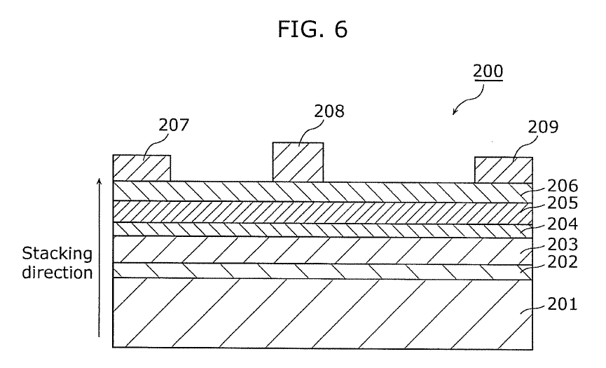

FIG. 6 is a cross-sectional view schematically showing a structure of an HEMT 200 according to Example 1.

As shown in FIG. 6, the HEMT 200 includes an undoped GaN layer 203, a crystallinity control layer 204, an undoped GaN layer 205, and an undoped AlGaN layer 206 that are sequentially stacked via a buffer layer 202 above a substrate 201. It is to be noted that the undoped GaN layers 203 and 205 are examples of third and fourth semiconductor layers according to the present invention, respectively.

The substrate 201 is, for instance, an Si substrate, SiC substrate, sapphire substrate, or GaN substrate. The buffer layer 202 is a semiconductor layer that is formed through low-temperature growth and made of AlN.

The crystallinity control layer 204 is a semiconductor layer that has a superlattice structure made of undoped AlN and GaN. A threading dislocation density increases in a stacking direction in the crystallinity control layer 204. The term “superlattice structure” here means a structure in which 20 pairs each of which is made of, for example, AlN having the film thickness of 5 nm and GaN having the film thickness of 20 nm are alternately stacked.

A film thickness of the undoped GaN layer 203 is, for instance, 1.5 μm, and a film thickness of the undoped GaN layer 205 is, for example, 1 μm.

The undoped GaN layers 203 and 205 each are a single semiconductor layer formed through regular crystal growth without addition of impurities, and thus a threading dislocation density decreases in a stacking direction in the undoped GaN layers 203 and 205. However, the threading dislocation density becomes greater in the crystallinity control layer 204, and thus the threading dislocation density of the undoped GaN layer 205 formed above the crystallinity control layer 204 becomes greater than the threading dislocation density of the undoped GaN layer 203 formed below the crystallinity control layer 204.

The undoped GaN layers 203 and 205 and the crystallinity control layer 204 are included in the first nitride semiconductor layer 103 in the HEMT 100 according to this embodiment. Likewise, the undoped AlGaN layer 206 is included in the second nitride semiconductor layer 104 in the HEMT 100 according to this embodiment.

The HEMT 200 further includes a source electrode 207, a gate electrode 208, and a drain electrode 209 that are formed side by side on the undoped AlGaN layer 206.

The source electrode 207 and the drain electrode 209 as ohomic electrodes each are formed of a Ti layer and an Al layer stacked on the undoped AlGaN layer 206. The gate electrode 208 as a Schottky electrode is formed of a Pt layer and an Au layer stacked on the undoped AlGaN layer 206.

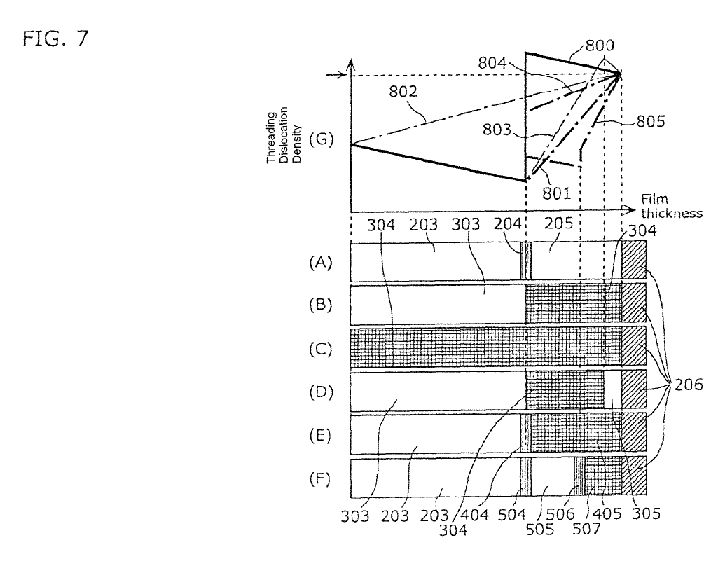

A schematic diagram of a film thickness direction dependence of a threading dislocation density in the HEMT 200 according to Example 1 is shown by a curve 800 in (G) in FIG. 7, and a schematic diagram of a crystal structure is shown by (A) in FIG. 7.

As shown by (A) and (G) in FIG. 7, although the undoped GaN layer 203 causes the threading dislocation density to monotonously decrease in the stacking direction (GaN growth direction), the superlattice structure of the crystallinity control layer 204 causes the threading dislocation density to temporarily increase. Subsequently, the undoped GaN layer 205 causes the threading dislocation density to decrease again in the stacking direction (GaN growth direction). As a result, a full width at half maximum of a (1012) line of an X-ray rocking curve in a contact plane of the undoped GaN layer 205 with the undoped AlGaN layer 206 becomes 1000 arc seconds, which is equivalent to the threading dislocation density of 4.4×10⁹ cm⁻². In such an HEMT 200, the degree of current collapse Raf/Rbf=2.8 is achieved, which reaches a level at which there is no practical issue. In addition, the film thickness of the first nitride semiconductor layer 103 is 2.5 μm as a whole, and the breakdown voltage at this time is 500 V, which is allowed to exceed the breakdown voltage of 400 V required for the commercial power supply in Japan.

As described above, in the HEMT 200 according to Example 1, the crystallinity control layer 204 controls the crystallinity of the channel, and the threading dislocation density is adjusted to be between 2×10⁹ cm⁻² and 1.6×10¹⁰ cm⁻² inclusive accordingly. Thus, it is possible to suppress the current collapse while limiting the sheet resistance within a practically usable range.

Furthermore, on top of the crystallinity control layer 204 having the high threading dislocation density, the undoped GaN layers 203 and 205 in which the threading dislocation density monotonously decreases in the stacking direction are provided in the HEMT 200 according to Example 1. Thus, it is possible to combine the suppression of the current collapse with the increase of the breakdown voltage.

### Example 2

Example 2 shows an application of the HEMT 100 according to this embodiment.

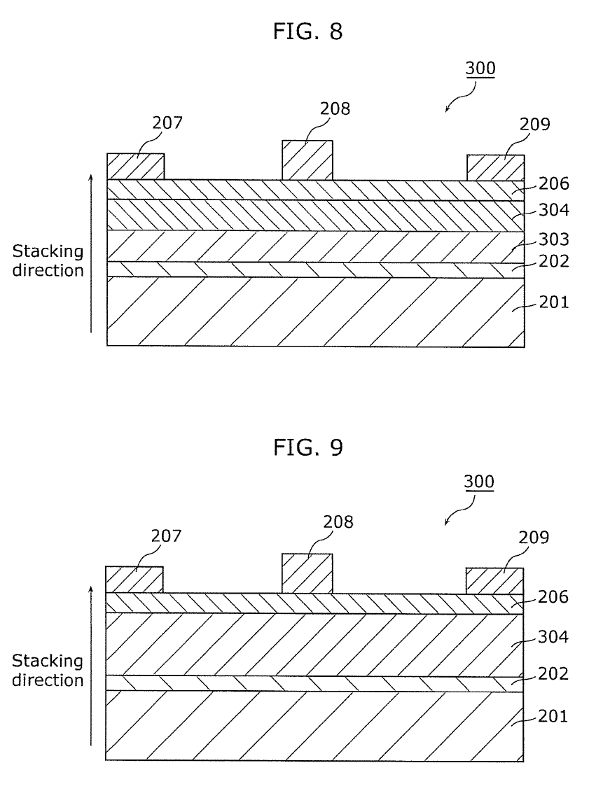

FIG. 8 is a cross-sectional view schematically showing a structure of an HEMT 300 according to Example 2.

As shown in FIG. 8, the HEMT 300 includes an undoped GaN Layer 303, a crystallinity control layer 304, and an undoped AlGaN layer 206 that are sequentially stacked via a buffer layer 202 above a substrate 201. The HEMT 300 further includes a source electrode 207, a gate electrode 208, and a drain electrode 209 that are formed side by side on the undoped AlGaN layer 206.

The crystallinity control layer 304 is, for instance, a semiconductor layer made of GaN having the film thickness of 1 μm, and is formed through crystal growth of GaN at a lower temperature (900° C. to 1000° C.) or a higher temperature (1040° C. to 1100° C.) than the regular growth temperature of 1020° C. Thus, a threading dislocation density gradually increases in the stacking direction in the crystallinity control layer 304.

A film thickness of the undoped GaN layer 303 is, for example, 1.5 μm. The undoped GaN layer 303 is a single semiconductor layer formed through regular crystal growth without addition of impurities, and thus a threading dislocation density decreases in the stacking direction.

The undoped GaN layer 303 and the crystallinity control layer 304 are included in the first semiconductor layer 103 of the HEMT 100 according to this embodiment.

A schematic diagram of a film thickness direction dependence of a threading dislocation density in the HEMT 300 according to Example 2 is shown by a curve 801 in (G) in FIG. 7, and a schematic diagram of a crystal structure is shown by (B) in FIG. 7.

As shown by (B) and (G) in FIG. 7, although the undoped GaN layer 303 causes the threading dislocation density to monotonously decrease in the stacking direction (GaN growth direction), the crystallinity control layer 304 causes the threading dislocation density to gradually increase in the stacking direction (GaN growth direction). When the crystallinity control layer 304 is formed by growing GaN having the thickness of 1 μm at the growth temperature of 1050° C., a full width at half maximum of a (1012) line of an X-ray rocking curve in a contact plane of the crystallinity control layer 304 with the undoped AlGaN layer 206 becomes 1050 arc seconds, which is equivalent to the threading dislocation density of 4.9×10⁹ cm⁻². With this, the degree of current collapse Raf/Rbf of the HEMT 300 becomes 2.7, and it is possible to suppress the current collapse to a level at which there is no practical issue.

It is to be noted that, in Example 2, the first nitride semiconductor layer 103 includes the undoped GaN layer 303 which is a region in which a threading dislocation density monotonously decreases, and the crystallinity control layer 304. However, the first nitride semiconductor layer 103 may include only the crystallinity control layer 304 which is a region in which a threading dislocation density monotonously increases. FIG. 9 is a cross-sectional view schematically showing a structure of the HEMT 300 in this case. A schematic diagram of a film thickness direction dependence of a threading dislocation density is shown by a curve 802 in (G) in FIG. 7, and a schematic diagram of a crystal structure is shown by (C) in FIG. 7. As shown by (C) and (G) in FIG. 7, the crystallinity control layer 304 causes the threading dislocation density to gradually increase in the stacking direction (GaN growth direction).

Similarly, the first nitride semiconductor layer 103 includes the undoped GaN layers 303 and 305 and the crystallinity control layer 304, and may include, above the crystallinity control layer 304, a region in which a threading dislocation density monotonously decreases. The undoped GaN layer 305 is a single semiconductor layer formed through regular crystal growth without addition of impurities. FIG. 10 is a cross-sectional view schematically showing a structure of the HEMT 300 in this case. A schematic diagram of a film thickness direction dependence of a threading dislocation density is shown by a curve 803 in (G) in FIG. 7, and a schematic diagram of a crystal structure is shown by (D) in FIG. 7. As shown by (D) and (G) in FIG. 7, although the crystallinity control layer 304 causes the threading dislocation density to gradually increase in the stacking direction (GaN growth direction), the undoped GaN layer 305 causes the threading dislocation density to gradually decrease in the stacking direction (GaN growth direction).

### Example 3

Example 3 shows an application of the HEMT 100 according to this embodiment.

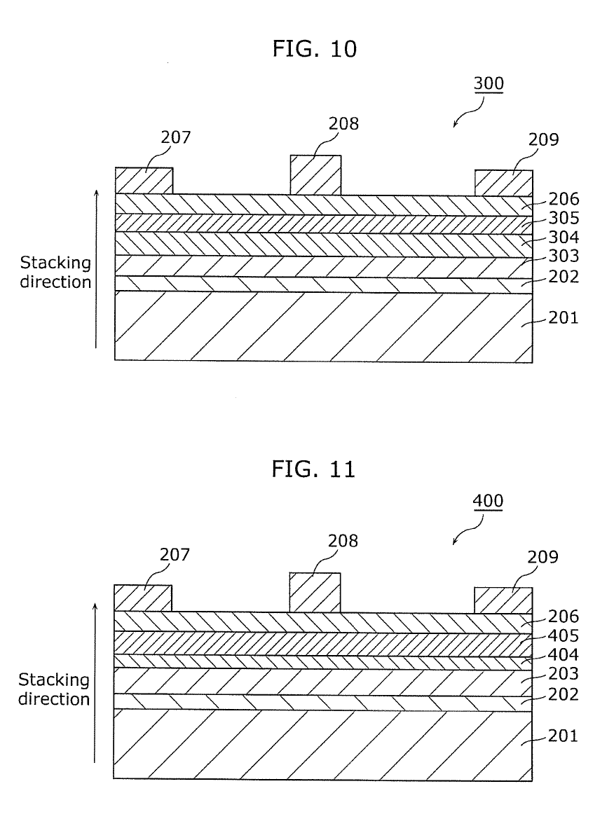

FIG. 11 is a cross-sectional view schematically showing a structure of an HEMT 400 according to Example 3.

As shown in FIG. 11, the HEMT 400 includes an undoped GaN layer 203, crystallinity control layers 404 and 405, and an undoped AlGaN layer 206 that are sequentially stacked via a buffer layer 202 above a substrate 201. The HEMT 400 further includes a source electrode 207, a gate electrode 208, and a drain electrode 209 that are formed side by side on the undoped AlGaN layer 206.

The crystallinity control layer 404 is a semiconductor layer having a superlattice structure made of undoped AlN and GaN. A threading dislocation density increases in a stacking direction in the crystallinity control layer 404. The term “superlattice structure” here means a structure in which 20 pairs each of which is made of, for example, AlN having the film thickness of 5 nm and GaN having the film thickness of 20 nm are alternately stacked.

The crystallinity control layer 405 is, for instance, a semiconductor layer made of GaN having the film thickness of 1 μm, and is formed through crystal growth of GaN at a lower temperature (900° C. to 1000° C.) or a higher temperature (1040° C. to 1100° C.) than the regular growth temperature of 1020° C. Thus, a threading dislocation density gradually increases in the stacking direction in the crystallinity control layer 405.

The undoped GaN layer 203 and the crystallinity control layers 404 and 405 are included in the first nitride semiconductor layer 103 in the HEMT 100 according to this embodiment.

A schematic diagram of a film thickness direction dependence of a threading dislocation density in the HEMT 400 according to Example 3 is shown by a curve 804 in (G) in FIG. 7, and a schematic diagram of a crystal structure is shown by (E) in FIG. 7.

As shown by (E) and (G) in FIG. 7, although the undoped GaN layer 203 causes the threading dislocation density to monotonously decrease in the stacking direction (GaN growth direction), the crystallinity control layer 404 causes the threading dislocation density to temporarily increase, and further the crystallinity control layer 405 causes the threading dislocation density to gradually increase in the stacking direction (GaN growth direction). As a result, a full width at half maximum of a (1012) line of an X-ray rocking curve in a contact plane of the crystallinity control layer 405 with the undoped AlGaN layer 206 becomes 1080 arc seconds, which is equivalent to the threading dislocation density of 5.2×10⁹ cm⁻². With this, the degree of current collapse Raf/Rbf of the HEMT 400 becomes 2.9, and it is possible to suppress the current collapse to a level at which there is no practical issue.

### Example 4

Example 4 shows an application of the HEMT 100 according to this embodiment.

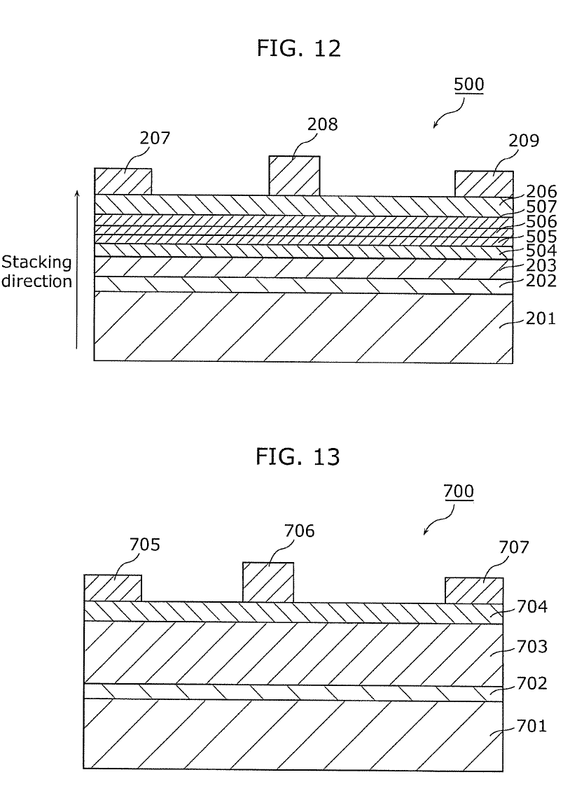

FIG. 12 is a cross-sectional view schematically showing a structure of an HEMT 500 according to Example 4.

As shown in FIG. 12, the HEMT 500 includes an undoped GaN layer 203, a crystallinity control layer 504, an undoped GaN layer 505, crystallinity control layers 506 and 507, and an undoped AlGaN layer 206 that are sequentially stacked via a buffer layer 202 above a substrate 201. The HEMT 500 further includes a source electrode 207, a gate electrode 208, and a drain electrode 209 that are formed side by side on the undoped AlGaN layer 206.

The crystallinity control layers 504 and 506 each are a semiconductor layer having a superlattice structure made of undoped AlN and GaN. A threading dislocation density increases in a stacking direction in the crystallinity control layers 504 and 506. The term “superlattice structure” here means a structure in which 20 pairs each of which is made of, for example, AlN having the film thickness of 5 nm and GaN having the film thickness of 20 nm are alternately stacked.

The undoped GaN layer 505 is a single semiconductor layer formed through regular crystal growth without addition of impurities, and thus a threading dislocation density decreases in the stacking direction. A film thickness of the undoped GaN layer 505 is, for example, 0.5 μm.

The crystallinity control layer 507 is, for instance, a semiconductor layer made of GaN having the film thickness of 1 μm, and is formed through crystal growth of GaN at a lower temperature (900° C. to 1000° C.) or a higher temperature (1040° C. to 1100° C.) than the regular growth temperature of 1020° C. Thus, a threading dislocation density gradually increases in the stacking direction in the crystallinity control layer 507.

The undoped GaN layer 203, the crystallinity control layers 504, 506, and 507, and the undoped GaN layer 505 are included in the first nitride semiconductor layer 103 in the HEMT 100 according to this embodiment.

A schematic diagram of a film thickness direction dependence of a threading dislocation density in the HEMT 500 according to Example 4 is shown by a curve 805 in (G) in FIG. 7, and a schematic diagram of a crystal structure is shown by (F) in FIG. 7.

As shown by (F) and (G) in FIG. 7, although the undoped GaN layer 203 causes the threading dislocation density to monotonously decrease in the stacking direction (GaN growth direction), the superlattice structure of the crystallinity control layer 504 causes the threading dislocation density to temporarily increase. Subsequently, the undoped GaN layer 505 causes the threading dislocation density to temporarily decrease, then the superlattice structure of the crystallinity control layer 506 causes the threading dislocation density to temporarily increase again, and further the crystallinity control layer 507 causes the threading dislocation density to gradually increase. As a result, a full width at half maximum of a (1012) line of an X-ray rocking curve in a contact plane of the crystallinity control layer 507 with the undoped AlGaN layer 206 becomes 1100 arc seconds, which is equivalent to the threading dislocation density of 5.3×10⁹ cm⁻². With this, the degree of current collapse Raf/Rbf of the HEMT 500 becomes 2.5, and it is possible to suppress the current collapse to a level at which there is no practical issue.

Although the field-effect transistor according to the present invention has been described above based on the embodiment, the present invention is not limited to the embodiment. Various modifications conceived and added to the embodiment by those skilled in the art are included within the scope of the present invention.

For example, the first nitride semiconductor layer 103 (GaN layer functioning as the channel) includes the crystallinity control layer in the embodiment. However, the present invention is not limited to this as long as a full width at half maximum of a (1012) line of an X-ray rocking curve in a contact plane of the first nitride semiconductor layer 103 with the second semiconductor layer 104 becomes between 800 and 1900 arc seconds inclusive and, when converted from the full width at half maximum, a threading dislocation density is between 2×10⁹ cm⁻² and 4.4×10¹⁰ cm⁻² inclusive. Such a region is formed by appropriately controlling formation conditions of the first nitride semiconductor layer 103.

To put it differently, the region is formed by inducing crystal growth of the GaN layer on the buffer layer 102 while increasing a flow ratio between ammonia and trimethylgallium (ratio between a Group 5 element and a Group 3 element) to be 1150 and by growing the GaN layer by 2 μm. In this case, a full width at half maximum of a (1012) line of an X-ray rocking curve in the channel becomes 950 arc seconds, which is equivalent to the threading dislocation density of 4.0×10⁹ cm⁻². With this, the degree of current collapse Raf/Rbf of the HEMT becomes 3.5, and it is possible to suppress the current collapse to a level at which there is no practical issue.

Moreover, the region is formed by doping impurities such as B, As, P, and N at the impurity concentration of 10¹⁶ cm⁻³ or higher, when the crystal growth of the GaN layer on the buffer layer 102 is induced. The formed GaN layer includes the impurities such as B, As, P, and N at the impurity concentration of 10¹⁶ cm⁻³ or higher. A difference in size of dopant atoms and N atoms distorts a lattice constant of GaN, which introduces a dislocation in the GaN layer. In this case, a full width at half maximum of a (1012) line of an X-ray rocking curve in the channel becomes 850 arc seconds, which is equivalent to the threading dislocation density of 3.2×10⁹ cm⁻². With this, the degree of current collapse Raf/Rbf of the HEMT becomes 3.8, and it is possible to suppress the current collapse to a level at which there is no practical issue.

Furthermore, although the first nitride semiconductor layer 103 is made of GaN in the embodiment, apart from GaN, the first nitride semiconductor layer 103 may be made of an Al_{1-x-y}GaₓIn_{y}N (0≦x≦1, 0≦y≦1) system semiconductor material including Al, In, and so on.

### INDUSTRIAL APPLICABILITY

The present invention is useful as a field-effect transistor, and especially as a power transistor in a power supply circuit of a consumer appliance such as an air conditioner.

What is claimed is:

1. A field-effect transistor comprising:
a first semiconductor layer made of a first nitride semiconductor; and
a second semiconductor layer formed on said first semiconductor layer and made of a second nitride semiconductor having a greater band gap than a band gap of said first nitride semiconductor,
wherein said first semiconductor layer includes a region in which a threading dislocation density increases in a stacking direction.

2. The field-effect transistor according to claim 1,
wherein said first semiconductor layer includes a third semiconductor layer, a crystallinity control layer formed on said third semiconductor layer, and a fourth semiconductor layer formed on said crystallinity control layer,
said crystallinity control layer has a threading dislocation density increasing in a stacking direction, and
said fourth semiconductor layer has a threading dislocation density greater than a threading dislocation density of said third semiconductor layer.

3. The field-effect transistor according to claim 1,
wherein a threading dislocation density in a contact plane of said first semiconductor layer with said second semiconductor layer is equal to or higher than 2×10⁹ cm⁻².

4. The field-effect transistor according to claim 1,
wherein said first semiconductor layer includes a region in which a threading dislocation density decreases in a stacking direction.

5. The field-effect transistor according to claim 4,
wherein said first semiconductor layer has a film thickness equal to or greater than 2 μm.

6. The field-effect transistor according to claim 5,
wherein said first semiconductor layer includes, as said region in which the threading dislocation density increases in the stacking direction, a layer having a superlattice structure made of GaN and AlN.

7. The field-effect transistor according to claim 5,
wherein said first semiconductor layer includes, as said region in which the threading dislocation density increases in the stacking direction, a layer which is made of GaN and formed through crystal growth at a temperature in a range of 900° C. to 1000° C. or a range of 1040° C. to 1100° C.

8. The field-effect transistor according to claim 5,
wherein said first semiconductor layer includes, as said region in which the threading dislocation density increases in the stacking direction, a layer including B, As, P, or N at an impurity concentration equal to or greater than 10¹⁶ cm⁻³.

9. The field-effect transistor according to claim 5,
wherein said first semiconductor layer is formed through crystal growth while increasing a ratio between a Group 5 element and a Group 3 element.

10. The field-effect transistor according to claim 1,
wherein said first semiconductor layer has a film thickness equal to or greater than 2 μm.

11. The field-effect transistor according to claim 1,
wherein said first semiconductor layer includes, as said region in which the threading dislocation density increases in the stacking direction, a layer having a superlattice structure made of GaN and AlN.

12. The field-effect transistor according to claim 1,
wherein said first semiconductor layer includes, as said region in which the threading dislocation density increases in the stacking direction, a layer which is made of GaN and formed through crystal growth at a temperature in a range of 900° C. to 1000° C. or a range of 1040° C. to 1100° C.

13. The field-effect transistor according to claim 1,
wherein said first semiconductor layer includes, as said region in which the threading dislocation density increases in the stacking direction, a layer including B, As, P, or N at an impurity concentration equal to or greater than 10¹⁶ cm⁻³.

14. The field-effect transistor according to claim 1,
wherein said first semiconductor layer is formed through crystal growth while increasing a ratio between a Group 5 element and a Group 3 element.
